(19) United States
(12) Patent Application Publication
(10) Pub. No.: US 2008/0096344 A1
(43) Pub. Date: Apr. 24, 2008

(54) Method for Manufacturing a Resistor Random Access Memory with a Self-Aligned Air Gap insulator

(75) Inventors: Erh-Kun Lai, Longjing Shiang (TW); ChiaHua Ho, Kaoshing (TW); Kuang Yeu Hsieh, Jhubei City (TW)

Correspondence Address: MACRONIX;C/O HAYNES BEFFEL & WOLFELD LLP, P. O. BOX 366, HALF MOON BAY, CA, 94019, US

(73) Assignee: Macronix International Co., Ltd., Hsinchu (TW)

(21) Appl. No.: 11/552,356

(22) Filed: Oct. 24, 2006

(51) Int. Cl. H01L 21/8239

(52) U.S. Cl. 438/238; 438/385

(57) ABSTRACT

A method for manufacturing a resistor random access memory with a self-aligned air gap insulator. A high density plasma deposition on the stack of post-patterned layers produces a hard mask that is substantially near the center and overlying the cap layer of the stack of post-patterned layers. The high density plasma deposition is performed with small critical dimensions so that a small triangle is generated over the cap layer and located near the center of the cap layer. The hard mask serves to prevent the area directly underneath the base of the hard mask from etching, while the hard mask provides a self-aligned technique for etching the left and right sections of the stack of post-patterned layers because the hard mask overlies and positions near the center of the stack of post-patterned layers.

### BACKGROUND OF THE INVENTION

1. Field of the Invention

The present invention relates generally to electrically programmable and erasable memory, and more particularly, to resolving a hard-to-erase condition under high cycle endurance in a charge trapping memory.

2. Description of Related Art

Phase change based memory materials are widely used in read-write optical disks. These materials have at least two solid phases, including for example a generally amorphous solid phase and a generally crystalline solid phase. Laser pulses are used in read-write optical disks to switch between phases and to read the optical properties of the material after the phase change.

Phase change based memory materials, like chalcogenide based materials and similar materials, can also be caused to change phase by application of electrical current at levels suitable for implementation in integrated circuits. The generally amorphous state is characterized by higher resistivity than the generally crystalline state, which can be readily sensed to indicate data. These properties have generated interest in using programmable resistive material to form nonvolatile memory circuits, which can be read and written with random access.

The change from the amorphous to the crystalline state is generally a lower current operation. The change from crystalline to amorphous, referred to as reset herein, is generally a higher current operation, which includes a short high current density pulse to melt or breakdown the crystalline structure, after which the phase change material cools quickly, quenching the phase change process, allowing at least a portion of the phase change structure to stabilize in the amorphous state. It is desirable to minimize the magnitude of the reset current used to cause the transition of phase change material from the crystalline state to the amorphous state. The magnitude of the reset current needed for reset can be reduced by reducing the size of the phase change material element in the cell and of the contact area between electrodes and the phase change material, so that higher current densities are achieved with small absolute current values through the phase change material element.

One direction of development has been toward forming small pores in an integrated circuit structure, and using small quantities of programmable resistive material to fill the small pores. Patents illustrating development toward small pores include: Ovshinsky, “Multibit Single Cell Memory Element Having Tapered Contact,” U.S. Pat. No. 5,687,112, issued Nov. 11, 1997; Zahorik et al., “Method of Making Chalogenide [sic] Memory Device,” U.S. Pat. No. 5,789,277, issued Aug. 4, 1998; Doan et al., “Controllable Ovonic Phase-Change Semiconductor Memory Device and Methods of Fabricating the Same,” U.S. Pat. No. 6,150,253, issued Nov. 21, 2000.

Problems have arisen in manufacturing such devices with very small dimensions, and with variations in process that meet tight specifications needed for large-scale memory devices. Heat dissipation generated from a phase change based memory material is also a factor to consider. It is therefore desirable to provide a memory cell with a smaller programmable resistive memory material with a reduction in heat dissipation.

### SUMMARY OF THE INVENTION

A method for manufacturing a resistor random access memory (RRAM) with a self-aligned air gap insulator is described. In a sequence of process steps, a stack of post-patterned layers by photolithography comprises a bottom electrode, a bottom heater layer overlying the bottom electrode, a programmable resistive memory film overlying the bottom heater layer, a top heater layer overlying the programmable resistive memory film and a cap layer overlying the top heater layer. A high density plasma (HDP) deposition on the stack of post-patterned layers produces a hard mask that is substantially near the center and overlying the cap layer of the stack of post-patterned layers. The hard mask can be created in various shapes, including a triangular shape or a trapezoidal shape. In one embodiment, the high density plasma deposition is carried out with a small critical dimension so that a relatively small triangle is generated over the cap layer and situated substantially near the center of the cap layer so that the distance from the left edge of the triangle to the left edge of the cap layer is the about same as the distance from the right edge of the triangle to the right edge of the cap layer. The hard mask serves to prevent the area directly underneath the base of the hard mask from being etched and the hard mask also provides a self-aligned technique for etching the left and right sections of the stack of post-patterned layers given that the hard mask overlies and is positioned substantially near the center of the stack of post-patterned layers. The etching process on the stack of post-patterned layers on each side of the hard mask may be a single anisotropic etch for the cap layer, the top heater layer, the programmable resistive memory film, and the bottom heater layer, or a two step process, first etching the cap layer with a first etch chemistry and second etching the top heater layer, the programmable resistive memory film, and the bottom heater layer with a second etch chemistry. A non-conformal and lower step coverage oxide deposition is carried out to form an air gap insulation surrounding the programmable resistive memory film for dissipating heat generated from the programmable resistive memory film.

A memory device is also disclosed that comprises a bit line overlying a top heater layer, the top heater layer overlying a programmable resistive memory film, the programmable resistive memory film overlying a bottom heater layer, and the bottom heater layer overlying a bottom electrode. Air gaps surrounding the programmable resistive memory film reduce heat dissipation generated from the programmable resistive memory material. An electrical current flows from the bit line, through the top heater layer, through the programmable resistive memory film, through the bottom layer, and to the bottom electrode.

Broadly stated, a method for manufacturing a memory device comprises disposing a plurality of layers over a top surface of a memory substrate, the plurality of layers includes a programmable resistive memory film, forming a hard mask having a geometric structure over the top surface of the plurality of layers by high density plasma deposition of a dielectric material with a specified critical dimension, the geometric structure of the hard mask having a base with a left edge and a right edge, etching vertically through the plurality of layers that exceed the left edge of the hard mask until reaching the top surface of the memory substrate and etching vertically through the plurality of layers that exceed the right edge of the hard mask until reaching the top surface of the memory substrate; and forming a first air gap adjacent to the left side of the programmable resistive memory film and a second air gap adjacent to the right side of the programmable resistive memory film by depositing dielectric over the hard mask and partially into a portion of the plurality of layers, the first and second air gaps dissipating heat generated from the programmable resistive memory film.

Advantageously, the present invention provides a bistable resistive randoum access memory with an air gap insulator that reduces heat dissipation generated from a programmable resistive memory film. The present invention also advantageously provides a self-aligned process in the manufacturing of the bistable resistive random access memory so that the programmable resistive memory film is self-aligned with approximately the same critical dimensions as the air gap insulator. The present invention further advantageously describes a smaller programmable resistive memory film in the memory cell structure with the air gap insulator.

The structures and methods of the present invention are disclosed in the detailed description below. This summary does not purport to define the invention. The invention is defined by the claims. These and other embodiments, features, aspects, and advantages of the invention will become better understood with reference to the following description, appended claims and accompanying drawings.

### BRIEF DESCRIPTION OF THE DRAWINGS

The invention will be described with respect to specific embodiments thereof, and reference will be made to the drawings, in which:

FIG. 1 is a schematic diagram of a bistable resistance random access memory array in accordance with the present invention.

FIG. 2 is a simplified block diagram of an integrated circuit in accordance with an embodiment of the present invention.

FIG. 3 is a simplified process diagram in a cross-sectional view of a bistable resistive random access memory with a self-aligned air gap insulator in accordance with the present invention.

FIG. 4 is a simplified process diagram in a cross-sectional view of the bistable resistive random access memory showing a first step with post-patterned layers, following photolithography fabricated on a memory array transistor structure in accordance with the present invention.

FIG. 5A is a process diagram in a cross-sectional view of the resistor random access memory showing a second step with a high density plasma deposition and wet dip of a triangular hard mask in accordance with the present invention; FIGS. 5B-C are experimental diagrams that illustrate an HDP deposition and a post HDP dip respectively in accordance with the present invention; and FIG. 5D is a pictorial diagram illustrating sample parameters of the high density plasma deposition of a triangular hard mask in accordance with the present invention.

FIG. 6 is a process diagram in a cross-sectional view of the resistor random access memory showing a third step using an etching technique to etch through each side of the HDP hard mask in accordance with the present invention.

FIG. 7 is a process diagram in a cross-sectional view of the resistor random access memory showing a fourth step of the process with non-conformal and lower step coverage of a dielectric deposition to form air gaps in accordance with the present invention.

FIG. 8 is a process diagram in a cross-sectional view of the resistor random access memory showing a fifth step in chemical mechanical polishing of the inter-metal dielectric in accordance with the present invention.

FIG. 9 is a process diagram in a cross-sectional view of the resistor random access memory showing a sixth step in the removal of the cap layer in accordance with the present invention.

FIG. 10 is a process diagram in a cross-sectional view of the resistor random access memory showing a seventh step in the deposition and patterning of a bit line in accordance with the present invention.

### DETAILED DESCRIPTION

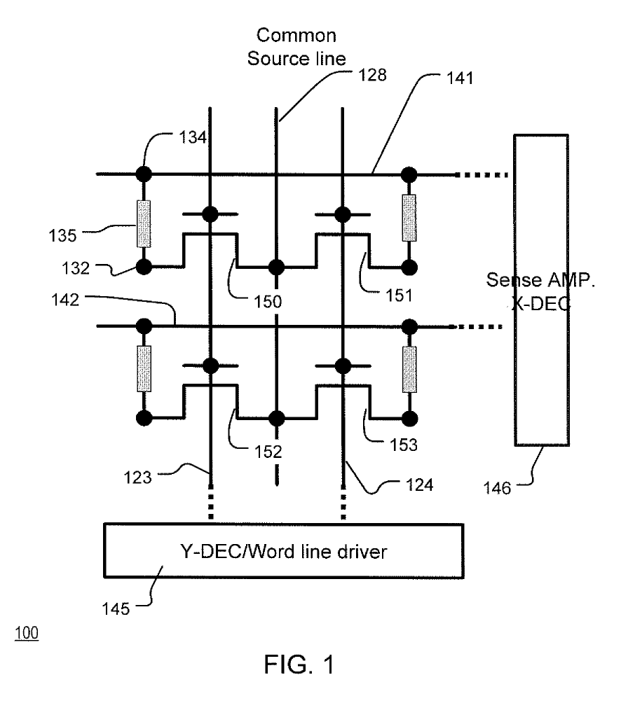

A description of structural embodiments and methods of the present invention is provided with reference to FIGS. 1-10. It is to be understood that there is no intention to limit the invention to the specifically disclosed embodiments but that the invention may be practiced using other features, elements, methods and embodiments. Like elements in various embodiments are commonly referred to with like reference numerals.

Referring now to FIG. 1, there is shown a schematic illustration of a memory array 100, which can be implemented as described herein. In the schematic illustration of FIG. 1, a common source line 128, a word line 123 and a word line 124 are arranged generally parallel in the Y-direction. Bit lines 141 and 142 are arranged generally parallel in the X-direction. Thus, a Y-decoder and a word line driver in a block 145 are coupled to the word lines 123, 124. An X-decoder and a set of sense amplifiers in block 146 are coupled to the hit lines 141 and 142. The common source line 128 is coupled to the source terminals of access transistors 150, 151, 152 and 153. The gate of access transistor 150 is coupled to the word line 123. The gate of access transistor 151 is coupled to the word line 124. The gate of access transistor 152 is coupled to the word line 123. The gate of access transistor 153 is coupled to the word line 124. The drain of access transistor 150 is coupled to the bottom electrode member 132 for memory cell 135, which has top electrode member 134 and a bottom electrode member 133. The top electrode member 134 is coupled to the bit line 141. It can be seen that the common source line 128 is shared by two rows of memory cells, where a row is arranged in the Y-direction in the illustrated schematic. In other embodiments, the access transistors can be replaced by diodes, or other structures for controlling current flow to selected devices in the array for reading and writing data.

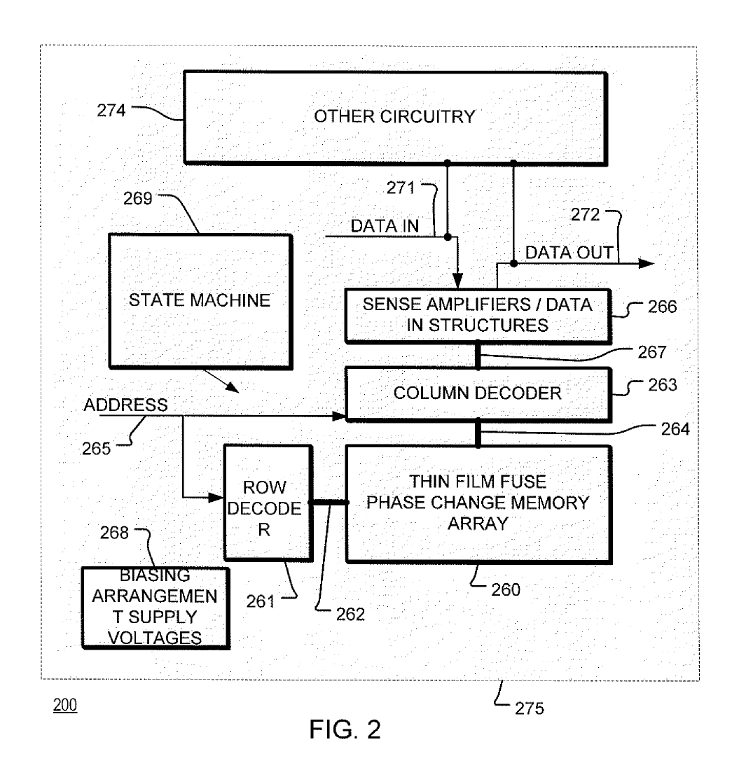

As illustrated in FIG. 2, there is shown a simplified block diagram of an integrated circuit 200 according to an embodiment of the present invention. The integrated circuit 275 includes a memory array implemented using bistable resistance random access memory cells, on a semiconductor substrate. A row decoder 261 is coupled to a plurality of word lines 262, and arranged along rows in the memory array 260. A column decoder 263 is coupled to a plurality of bit lines 264 arranged along pins in the memory array 260 for reading and programming data from the memory cells in the memory array 260. Addresses are supplied on a bus 265 to a column decoder 263 and a row decoder 261. Sense amplifiers and data-in structures in a block 266 are coupled to the column decoder 263 via a data bus 267. Data is supplied via the data-in line 271 from input/output ports on the integrated circuit 275 or from other data sources internal or external to the integrated circuit 275, to the data-in structures in the block 266. In the illustrated embodiment, other circuitry 274 is included on the integrated circuit 275, such as a general purpose processor or special purpose application circuitry, or a combination of modules providing system-on-a-chip functionality supported by the thin film fuse bistable resistance random access memory cell array. Data is supplied via the data-out line 272 from the sense amplifiers in block 266 to input/output ports on the integrated circuit 275, or to other data destinations internal or external to the integrated circuit 275.

A controller implemented in this example using bias arrangement state machine 269 controls the application of bias arrangement supply voltages 268, such as read, program, erase, erase verify and program verify voltages. The controller can be implemented using special-purpose logic circuitry as known in the art. In alternative embodiments, the controller comprises a general-purpose processor, which may be implemented on the same integrated circuit which executes a computer program to control the operations of the device. In yet other embodiments, a combination of special-purpose logic circuitry and a general-purpose processor may be utilized for implementation of the controller.

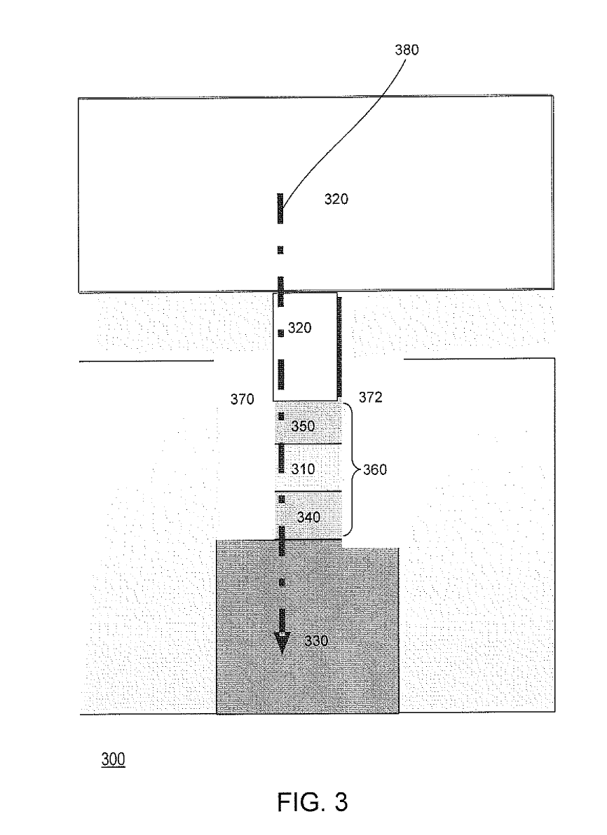

FIG. 3 illustrates a simplified process diagram in a cross-sectional view of a bistable resistive random access memory cell 300 with a self-aligned air gap insulator. The memory cell 300 comprises a programmable resistive memory film 310 disposed between a top electrode (e.g. a bit line) 320 and a bottom electrode 330. A bottom heater layer 340 is disposed between the programmable resistive memory film 310 and the bottom electrode 330. A top heater layer 350 is disposed between the programmable resistive memory film 310 and the bottom electrode 330. A stack 360 comprises the top heater layer 350 overlying the programmable resistive memory film 310. The programmable resistive memory film 310 overlies the bottom heater 340 which substantially aligned with the center of a top surface of the bottom electrode 330. The left side and the right side of the stack 360 are etched to create an air gap insulator that comprises a first air gap 370 and a second air gap 372. The air gap insulator surrounds the programmable resistive memory film 310. The width of the top surface of the bottom electrode is wider than the stack 360 such that the first air gap 370 extends between the bottom electrode 330 and the top electrode 320 and the second air gap 372 extends between the bottom electrode 330 and the top electrode 320. As illustrated in this embodiment, an electrical current 380 flows from the top electrode 320 to the bottom electrode 330. For example, as shown in FIG. 1, if the resistive random access memory cell 300 is implemented in the memory array 100, the current path flows from the top electrode 320 to the bottom electrode 330 due to MOS transistors steering the direction of the electrical current. In other embodiments, the electrical current 380 can flow bi-directionally in the resistive random access memory. That is, the current path of the electrical current 380 can flow from the top electrode 320 to the bottom electrode 330, or from the bottom electrode 330 to the top electrode 320.

The manufacturing of the programmable resistive memory material 310 is self aligned such that the programmable resistive memory material 310 is aligned near the center of the top surface of the bottom electrode 330, which is further described below with respect to the manufacturing process. The programmable resistive memory material 310 generates heat during the phase change from one state to another state. The air gaps 370, 372 surrounding the programmable resistive memory material 310 enhance heat dissipation emanating from the programmable resistive memory material 310. In one embodiment, each of the air gaps 370, 372 has substantially the same critical dimensions because of the manufacturing method described below which results in the self-aligned process with the air gaps 370, 372 disposed equally on each side of the programmable resistive memory film 310.

Embodiments of the memory cell include phase change based memory materials, including chalcogenide based materials and other materials, for the programmable resistive memory film 310. Chalcogens include any of the four elements oxygen (O), sulfur (S), selenium (Se), and tellurium (Te), forming part of group VI of the periodic table. Chalcogenides comprise compounds of a chalcogen with a more electropositive element or radical. Chalcogenide alloys comprise combinations of chalcogenides with other materials such as transition metals. A chalcogenide alloy usually contains one or more elements from column six of the periodic table of elements, such as germanium (Ge) and tin (Sn). Often, chalcogenide alloys include combinations including one or more of antimony (Sb), gallium (Ga), indium (In), and silver (Ag). Many phase change based memory materials have been described in technical literature, including alloys of: Ga/Sb, In/Sb, In/Se, Sb/Te, Ge/Te, Ge/Sb/Te, In/Sb/Te, Ga/Se/Te, Sn/Sb/Te, In/Sb/Ge, Ag/In/Sb/Te, Ge/Sn/Sb/Te, Ge/Sb/Se/Te and Te/Ge/Sb/S. In the family of Ge/Sb/Te alloys, a wide range of alloy compositions may be workable. The compositions can be characterized as TeₐGe_{b}Sb_{100-(a+b)}. One researcher has described the most useful alloys as having an average concentration of Te in the deposited materials well below 70%, typically below about 60% and ranged in general from as low as about 23% up to about 58% Te and most preferably about 48% to 58% Te. Concentrations of Ge were above about 5% and ranged from a low of about 8% to about 30% average in the material, remaining generally below 50%. Most preferably, concentrations of Ge ranged from about 8% to about 40%. The remainder of the principal constituent elements in this composition was Sb. These percentages are atomic percentages that total 100% of the atoms of the constituent elements. (Ovshinsky '112 patent, cots 10-11.) Particular alloys evaluated by another researcher include Ge₂Sb₂Te₅, GeSb₂Te₄ and GeSb₄Te₇. (Noboru Yamada, “Potential of Ge—Sb—Te Phase-Change Optical Disks for High-Data-Rate Recording”, SPIE v.3109, pp. 28-37 (1997).) More generally, a transition metal such as chromium (Cr), iron (Fe), nickel (Ni), niobium (Nb), palladium (Pd), platinum (Pt) and mixtures or alloys thereof may be combined with Ge/Sb/Te to form a phase change alloy that has programmable resistive properties. Specific examples of memory materials that may be useful are given in Ovshinsky '112 at columns 11-13, which examples are hereby incorporated by reference.

Phase change alloys are capable of being switched between a first structural state in which the material is in a generally amorphous solid phase, and a second structural state in which the material is in a generally crystalline solid phase in its local order in the active channel region of the cell. These alloys are at least bistable. The term amorphous is used to refer to a relatively less ordered structure, more disordered than a single crystal, which has the detectable characteristics such as higher electrical resistivity than the crystalline phase. The term crystalline is used to refer to a relatively more ordered structure, more ordered than an amorphous structure, which has detectable characteristics such as lower electrical resistivity than the amorphous phase. Typically, phase change materials may be electrically switched between different detectable states of local order across the spectrum between completely amorphous and completely crystalline states. Other material characteristics affected by the change between amorphous and crystalline phases include atomic order, free electron density and activation energy. The material may be switched either into different solid phases or into mixtures of two or more solid phases, providing a gray scale between completely amorphous and completely crystalline states. The electrical properties in the material may vary accordingly.

Phase change alloys can be changed from one phase state to another by application of electrical pulses. It has been observed that a shorter, higher amplitude pulse tends to change the phase change material to a generally amorphous state. A longer, lower amplitude pulse tends to change the phase change material to a generally crystalline state. The energy in a shorter, higher amplitude pulse is high enough to allow for bonds of the crystalline structure to be broken and short enough to prevent the atoms from realigning into a crystalline state. Appropriate profiles for pulses can be determined, without undue experimentation, specifically adapted to a particular phase change alloy. In following sections of the disclosure, the phase change material is referred to as GST, and it will be understood that other types of phase change materials can be used. A material useful for implementation of a PCRAM described herein is Ge₂Sb₂Te₅.

Other programmable resistive memory materials may be used in other embodiments of the invention, including N₂ doped GST, GeₓSb_{y}, or other material that uses different crystal phase changes to determine resistance; PrₓCa_{y}MnO₃, PrSrMnO₃, ZrOx, or other material that uses an electrical pulse to change the resistance state; 7,7,8,8-tetracyanoquinodimethane (TCNQ), methanofullerene 6,6-phenyl C61-butyric acid methyl ester (PCBM), TCNQ-PCBM, Cu-TCNQ, Ag-TCNQ, C60-TCNQ, TCNQ doped with other metal, or any other polymer material that has bistable or multi-stable resistance state controlled by an electrical pulse.

The following are short summaries describing four types of resistive memory materials. The first type is chalcogenide material, such as GeₓSb_{y}Te_{z} where x:y:z 2:2:5, or other compositions with x: 0˜5; y: 0˜5; z: 0˜10. GeSbTe with doping, such as N—, Si—, Ti—, or other element doping is alternatively used.

An exemplary method for forming chalcogenide material uses PVD-sputtering or a magnetron-sputtering method with source gas(es) of Ar, N₂, and/or He, etc. at the pressure of 1 mTorr˜100 mTorr. The deposition is usually performed at room temperature. A collimator with an aspect ratio of 1˜5 can be used to improve the fill-in performance. To improve the fill-in performance, a DC bias of several tens of volts to several hundreds of volts is also used. On the other hand, the combination of DC bias and the collimator can be used simultaneously.

A post-deposition annealing treatment in vacuum or in an N₂ ambient is optionally performed to improve the crystallized state of chalcogenide material. The annealing temperature typically ranges from 100° C. to 400° C. with an annealing time of less than 30 minutes.

The thickness of chalcogenide material depends on the design of a cell structure. In general, a chalcogenide material with thickness of higher than 8 nm can have a phase change characterization so that the material exhibits at least two stable resistance states.

A second type of memory material suitable for use in embodiments is colossal magnetoresistance (“CMR”) material, such as PrₓCa_{y}MnO₃ where x:y=0.5:0.5, or other compositions with x: 0˜1; y: 0˜1. CMR material that includes Mn oxide is alternatively used.

An exemplary method for forming CMR material uses PVD sputtering or a magnetron-sputtering method with source gases of Ar, N₂, O₂, and/or He, etc. at the pressure of 1 mTorr˜100 mTorr. The deposition temperature can range from room temperature to ˜600° C., depending on the post deposition treatment condition. A collimator with an aspect ratio of 1˜5 can be used to improve the fill-in performance. To improve the fill-in performance, the DC bias of several tens of volts to several hundreds of volts is also used. On the other hand, the combination of DC bias and the collimator can be used simultaneously. A magnetic field of several tens of Gauss to as much as a Tesla (10,000 Gauss) may be applied to improve the magnetic crystallized phase.

A post-deposition annealing treatment in vacuum or in an N₂ ambient or O₂/N₂ mixed ambient is optionally used to improve the crystallized state of CMR material. The annealing temperature typically ranges from 400° C. to 600° C. with an anneal time of less than 2 hours.

The thickness of CMR material depends on the design of the cell structure. The CMR thickness of 10 nm to 200 nm can be used for the core material. A buffer layer of YBCO (YBaCuO₃, which is a type of high temperature superconductor material) is often used to improve the crystallized state of CMR material. The YBCO is deposited before the deposition of CMR material. The thickness of YBCO ranges from 30 nm to 200 nm.

A third type of memory material is two-element compounds, such as NiₓO_{y}; TiₓO_{y}; AlₓO_{y}; WₓO_{y}; ZnₓO_{y}; ZrₓO_{y}; CuₓO_{y}; etc, where x:y=0.5:0.5, or other compositions with x: 0˜1; y: 0˜1. An exemplary formation method uses a PVD sputtering or magnetron-sputtering method with reactive gases of Ar, N₂, O₂, and/or He, etc. at the pressure of 1 mTorr˜100 mTorr, using a target of metal oxide, such as NiₓO_{y}; TiₓO_{y}; AlₓO_{y}; WₓO_{y}; ZnₓO_{y}; ZrₓO_{y}; CuₓO_{y}; etc. The deposition is usually performed at room temperature. A collimator with an aspect ratio of 1˜5 can be used to improve the fill-in performance. To improve the fill-in performance, a DC bias of several tens of volts to several hundreds of volts is also used. If desired, a combination of DC bias and the collimator can be used simultaneously.

A post-deposition annealing treatment in vacuum or in an N₂ ambient or O₂>N2 mixed ambient is optionally performed to improve the oxygen distribution of metal oxide. The annealing temperature ranges from 400° C. to 600° C. with an anneal time of less than 2 hours.

An alternative formation method uses a PVD sputtering or magnetron-sputtering method with reactive gases of Ar/O₂, Ar/N₂/O₂, pure O₂, He/O₂, He/N₂/O₂ etc. at the pressure of 1 mTorr 100 mTorr, using a target of metal oxide, such as Ni, Ti, Al, W, Zn, Zr, or Cu etc. The deposition is usually performed at room temperature. A collimator with an aspect ratio of 1˜5 can be used to improve the fill-in performance. To improve the fill-in performance, a DC bias of several tens of volts to several hundreds of volts is also used. If desired, the combination of DC bias and the collimator can be used simultaneously.

A post-deposition annealing treatment in vacuum or in an N₂ ambient or O₂/N₂ mixed ambient is optionally performed to improve the oxygen distribution of metal oxide. The annealing temperature ranges from 400° C. to 600° C. with an annealing time of less than 2 hours.

Yet another formation method uses oxidation by a high temperature oxidation system, such as a furnace or a rapid thermal pulse (“RTP”) system. The temperature ranges from 200° C. to 700° C. with pure O₂ or N₂/O₂ mixed gas at a pressure of several mTorr to 1 atm. The time can range from several minutes to hours. Another oxidation method is plasma oxidation. An RF or a DC source plasma with pure O₂ or Ar/O₂ mixed gas or Ar/N₂/O₂ mixed gas at a pressure of 1 mTorr to 100 mTorr is used to oxidize the surface of metal, such as Ni, Ti, Al, W, Zn, Zr, or Cu etc. The oxidation time ranges several seconds to several minutes. The oxidation temperature ranges from room temperature to 300° C., depending on the degree of plasma oxidation.

A fourth type of memory material is a polymer material, such as TCNQ with doping of Cu, C₆₀, Ag etc. or PCBM-TCNQ mixed polymer. One formation method uses evaporation by thermal evaporation, e-beam evaporation, or molecular beam epitaxy (“MBE”) system. A solid-state TCNQ and dopant pellets are co-evaporated in a single chamber. The solid-state TCNQ and dopant pellets are put in a W-boat, or a Ta-boat or a ceramic boat. A high electrical current or an electron-beam is applied to melt the source so that the materials are mixed and deposited on wafers. There are no reactive chemistries or gases. The deposition is performed at a pressure of 10⁻⁴ Torr to 10⁻¹⁰ Torr. The wafer temperature ranges from room temperature to 200° C.

A post-deposition annealing treatment in vacuum or in an N₂ ambient is optionally performed to improve the composition distribution of polymer material. The annealing temperature ranges from room temperature to 300° C. with an annealing time of less than 1 hour.

Another technique for forming a layer of polymer-based memory material is to use a spin-coater with doped-TCNQ solution at a rotation of less than 1000 rpm. After spin-coating, the wafer is held (typically at room temperature or temperature less than 200° C.) for a time sufficient for solid-state formation. The hold time ranges from several minutes to days, depending on the temperature and on the formation conditions.

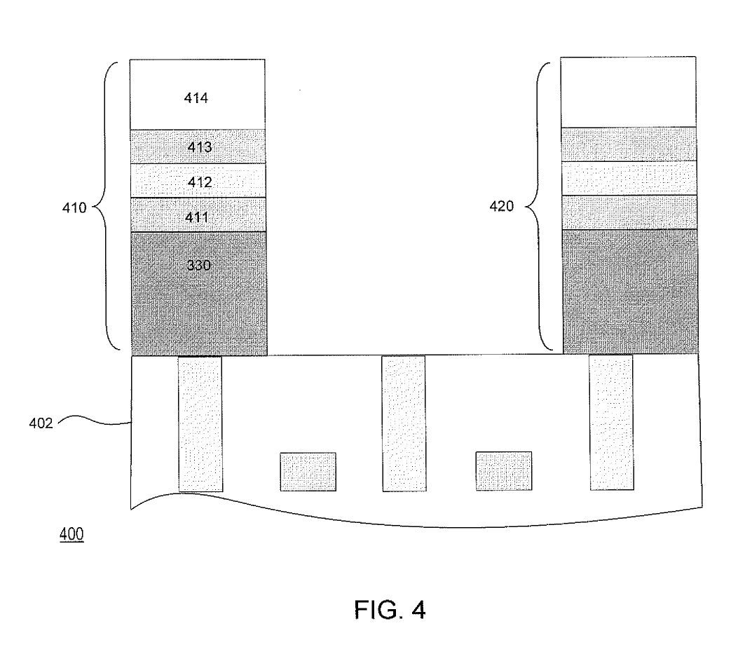

A method in the manufacturing of the bistable resistive random access memory 400 is discussed with reference to FIGS. 4-10. FIG. 4 illustrates a simplified process diagram in a cross-sectional view of the bistable resistive random access memory 400 showing a first step with a post-patterned fabricated on a memory array transistor structure 402 after photolithography. The memory array transistor structure, such as a memory common source array transistor structure, is known in the art. After a post-patterned process, a first partially fabricated memory cell 410 and a second partially fabricated memory cell 420 are positioned over the memory array transistor structure. The first partially fabricated memory cell 410 comprises the same structural layers as the second partially fabricated memory cell 420. The description below with respect to the first partially fabricated memory cell 410 is also applicable to the second partially fabricated memory cell 420. The first partially fabricated memory cell 410 comprises a cap layer 414 overlying a top heater layer 413, the top heater layer 413 overlying the programmable resistive memory film 412, the programmable resistive memory film 412 overlying a bottom heater layer 411, and the bottom heater layer 411 overlying the bottom electrode 330.

Titanium nitride is an example of a suitable material for implementing the bottom heater layer 411 and the top heater layer 413 because titanium nitride possesses properties that perform well with the programmable resistive memory film 412. An exemplary thickness, intended as but not limited to, an illustration for each of top heater layer 413 and the bottom heater layer 411 ranges from about 100 Å to about 1000 Å. The programmable resistive memory film 412 has a thickness that ranges from about 200 Å to 1000 Å in one embodiment. The bottom electrode 330 can be implemented with a conductive material such as aluminum (Al), titanium nitride (TiN) or metal. The cap layer 414 has an exemplary thickness that ranges from about 300 Å to about 1000 Å, and can be implemented with a material such as silicon nitride. The critical dimension of the first partially fabricated memory 410 ranges from about 50 nm to about 200 nm.

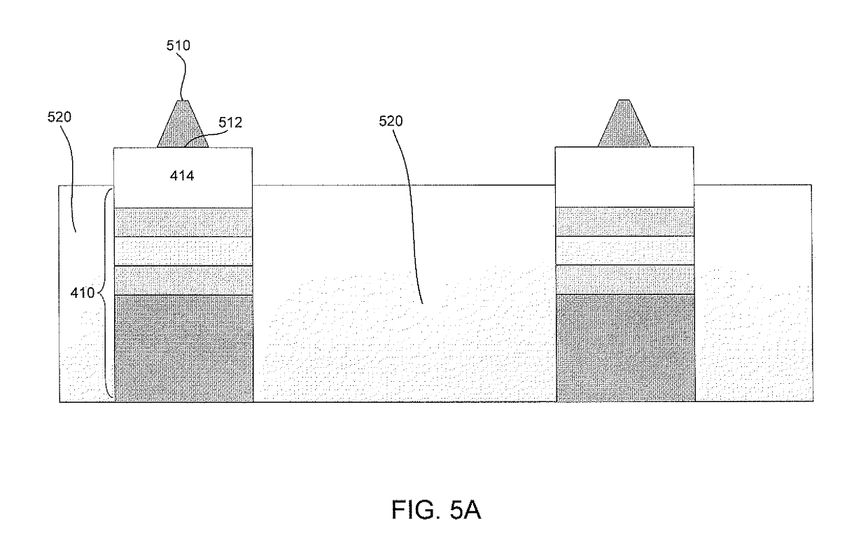

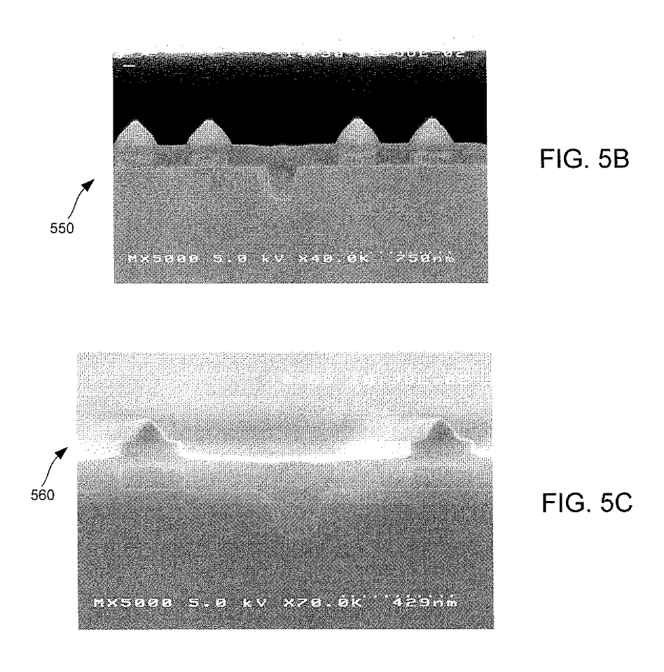

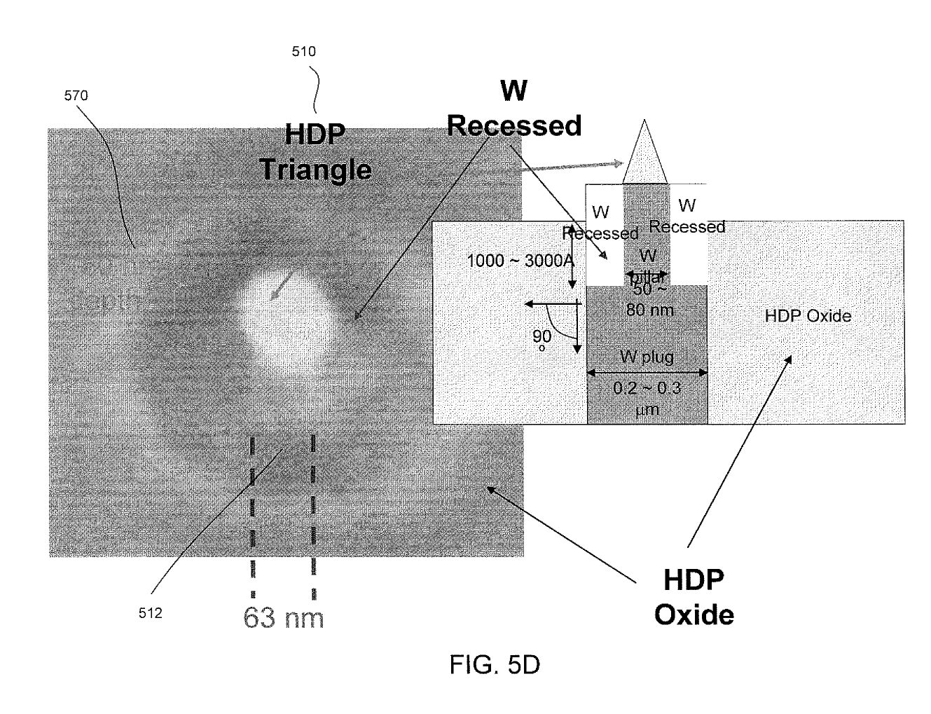

FIG. 5A illustrates a process diagram in a cross-sectional view of the resistor random access memory showing a second step with a high density plasma (HDP) deposition and wet dip of a triangular-shape hard mask. Two experimental graphs 550, 560 that illustrate a HDP deposition and a post high density plasma dip respectively are shown in FIGS. 5B and 5C. In a first process sequence, the high density plasma deposition process deposits a dielectric with a geometric shape 510, such as a triangular shape or a trapezoidal shape, over the cap layer 414 and a dielectric 520 around side walls of the first partially fabricated memory cell 410. In the next process sequence, a wet dip such as high density plasma dip is used to expose the cap layer 414 to form the geometric shape 510. The diagrams in FIGS. 5B and 5C show sample experimental shots of a flash memory, with a trapezoidal shape in FIG. 5B and a triangular shape in FIG. 5C. The geometric shape of either a trapezoidal shape or a triangular shape is controlled by using a dip process or HDP dep process. In one embodiment, the geometric shape 510 has a small critical dimension with a base 512. The following parameters are intended as an illustration and should not be construed to limit the scope of the present invention. The dimension of the base 512 is approximately 63 nm. The geometric shape 510 can range from 20˜100 nm with the process as described above. On the one hand, the high density plasma deposition of the geometric shape 510 is more likely to produce a triangular shape with angular sides if the critical dimension is small. On the other hand, the high density plasma deposition of the geometric shape 510 is likely to produce a trapezoid shape with more sides that are more vertical if the critical dimension is larger. The following parameters are intended as an illustration and should not be construed to limit the scope of the present invention. The dimension of the base 512 is approximately 63 nm. The geometric shape 510, such as the HDP deposition producing a trapezoidal-shape hard mask, can range from 20˜100 nm. FIG. 5D is a pictorial diagram illustrating sample parameters of the high density plasma deposition of a triangular hard mask. Specific values given in FIG. 5D are intended as illustrations in implementing one embodiment of the present invention. In this illustration, the geometric shape 510 includes the base 512 with a dimension of about 63 nm, and a depth 570 of approximately 150 nm.

The amount of plasma power in high density plasma deposition also affects the eventual shape of the geometric shape 510, even if the geometric shape 510 has a smaller critical dimension. In situations where the amount of plasma power is a higher value, the etching rate is also higher, but the deposition rate is slower, which results in the geometric shape 510 that has sides that are more angular, resembling more of a triangular shape. In situations where the amount of plasma power is a lower value, the etching rate is also lower, but the deposition rate is higher, which results in the geometric shape 510 that has sides that are more vertical, resembling more of a trapezoidal shape.

When the HDP inside etching process is applied, the original photolithography condition of the layer 410 could be larger, such as in the range of 100 nm. The final critical dimension of RRAM could be about 20 nm, which is more aggressive number than direct patterning. If a spacer is applied, the original photo should be about 20 nm, which may require a different tool to attain the critical dimension. In one embodiment, high density plasma deposition of an oxide material forms the geometric shape 510. Silicon nitride is used for the cap layer 414, thereby providing a contrasting material between the geometric shape 510 and cap layer 414 for selective etching. In another embodiment, high density plasma deposition of a silicon nitride material forms the geometric shape 510. An oxide is used to implement the cap layer 414, thereby providing a contrasting material between the geometric shape 510 and cap layer 414 for selective etching.

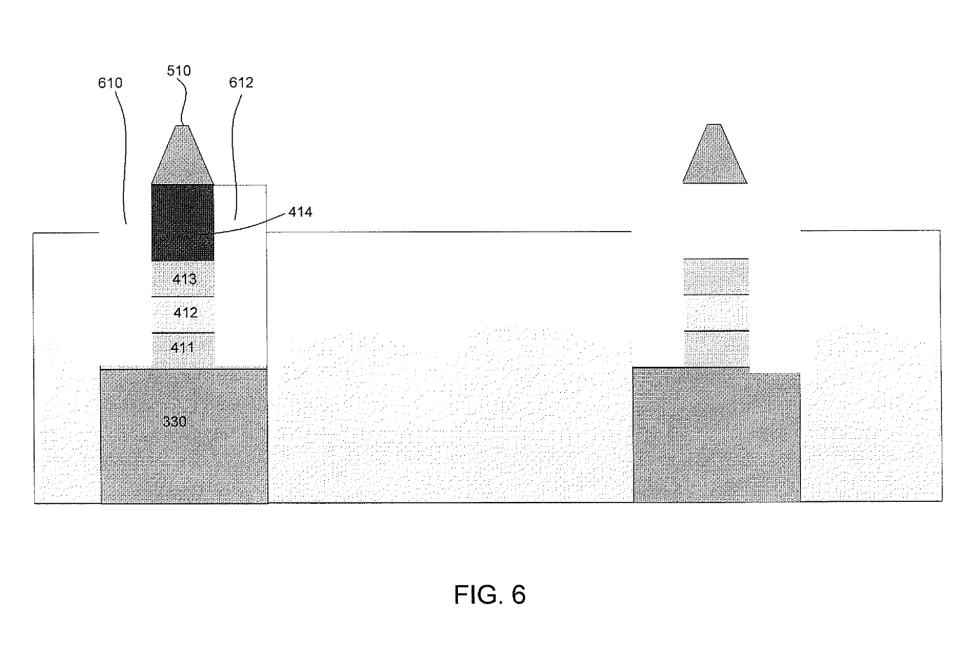

FIG. 6 illustrates a process diagram in a cross-sectional view of the resistor random access memory showing a third step with an etching technique through each side of the HDP hard mask 510. The HDP hard mark 510 is positioned at a substantially center location relative to the cap layer 414, the top heater layer 413, the programmable resistive memory film 412, the bottom heater layer 411 and the bottom electrode 330. As an illustration, the HDP hard mask 510 has a base that has a length of about 10 nm. Each side of the hard mask 510 is etched to create a first gap 610 on the left side and a second gap 612 on the right side. In the left direction and underneath the hard mask 510, the left sides of the cap layer 414, the top heater layer 413, the programmable resistive memory film 412, and the bottom heater layer 411 are etched until reaching the top surface of the bottom electrode 330 to create the first gap 610. Similarly, In the right direction and underneath the hard mask 510, the right sides of the cap layer 414, the top heater layer 413, the programmable resistive memory film 412, and the bottom heater layer 411 are etched until reaching the top surface of the bottom electrode 330 to create the second gap 612. In one embodiment, the critical dimension of the first gap 610 is the same as the critical dimension of the second gap 612; in other words, the hard mark 510 is located substantially near the center such that the etching through of the cap layer 414, the top heater layer 413, the programmable resistive memory film 412, and the bottom heater layer 411 is about the same on each side of the hard mask 510.

The etching process may be a single etch process through the cap layer 414, the top heater layer 413, the programmable resistive memory film 412, and the bottom heater layer 411 until reaching the top surface of the bottom electrode 330, or it may be a two step process, first etching the cap layer 414 with a first etching chemistry and second using the HDP oxide and the cap layer (e.g., silicon nitride) as a hard mask to etch the top heater layer 413, the programmable resistive memory film 412, and the bottom heater layer 411. In one embodiment, each of the first gap 610 and the second gap 612 has a critical dimension that ranges from about 20 nm to about 50 nm.

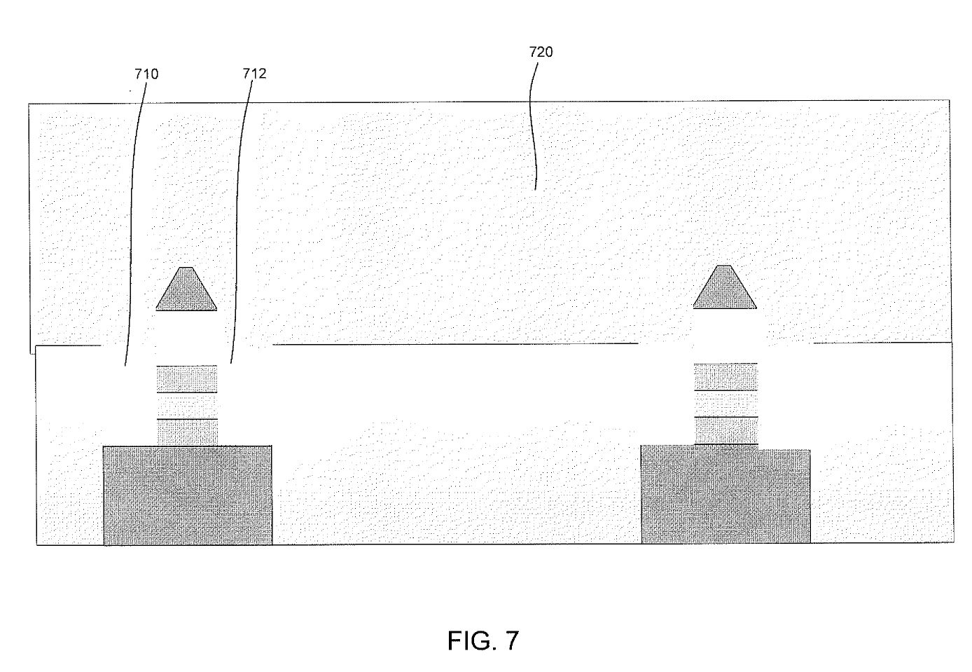

FIG. 7 illustrates a process diagram in a cross-sectional view of the resistor random access memory showing a fourth step of a non-conformal and low step coverage of a dielectric deposition to form an air gap. The term “non-conformal and low deposition” includes deposition of non-conformal and lower step coverage of dielectric deposition of the air gap, and lower conformal and lower step coverage of dielectric deposition of the air gap. A suitable deposition of the dielectric 720 is implemented using an atmospheric pressure chemical vapor deposition (APCVD), where chemical vapor deposition is processed at atmospheric pressure to form the first air gap 710 and the second air gap 712.

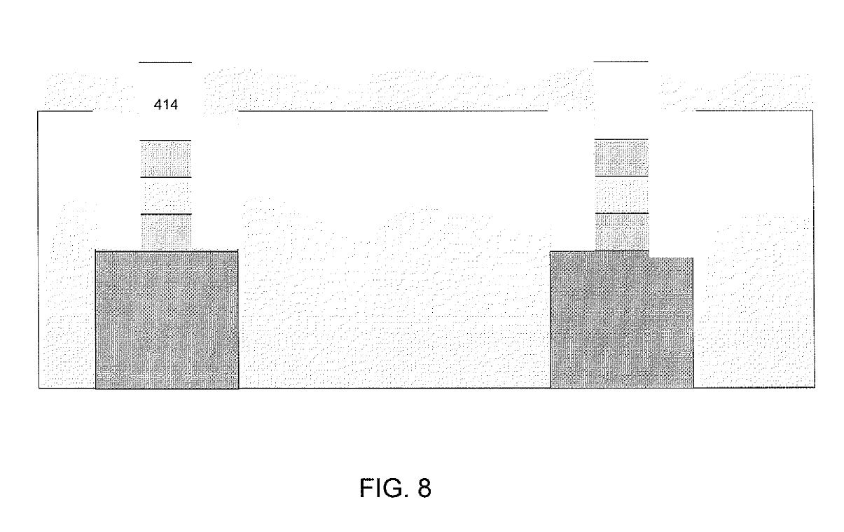

FIG. 8 is a process diagram in a cross-sectional view of the resistor random access memory showing a fifth step in chemical mechanical polishing of the inter-metal dielectric 720. The inter-metal dielectric 720 is polished to the top surface of the cap layer 414, thereby removing a portion of the inter-metal dielectric 720 that goes beyond the top surface of the cap layers 414 and the hard mask 510. Embodiments of the process for polishing include a chemical mechanical polishing process, followed by optional brush clean and liquid and or gas clean procedures, as known in the art.

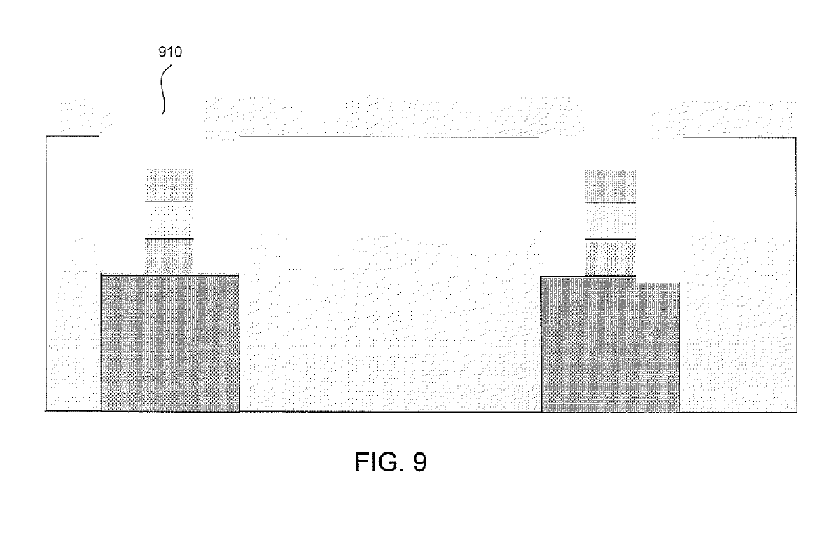

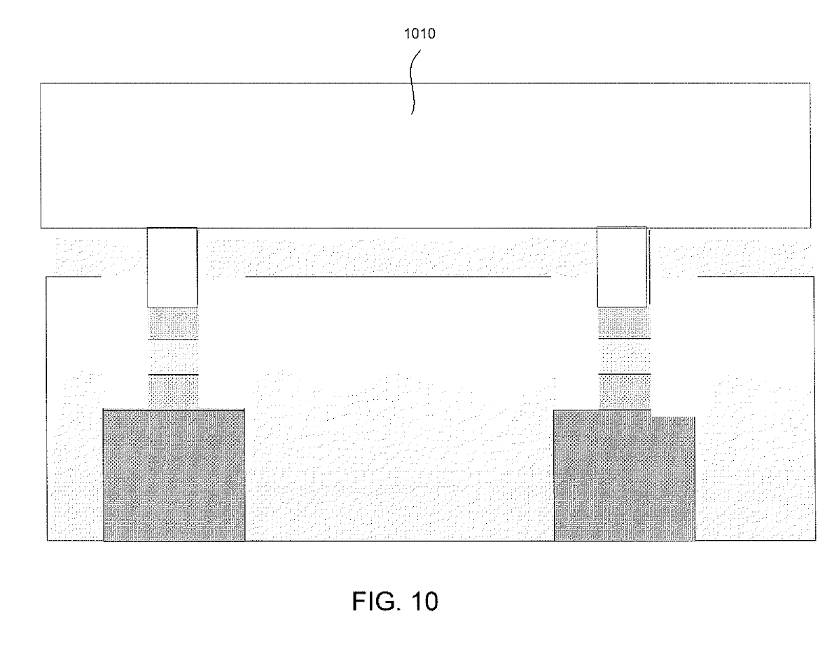

FIG. 9 is a process diagram in a cross-sectional view of the resistor random access memory showing a sixth step in the removal of the cap layer 414. The cap layer 414 is etched away from the first partially fabricated memory cell 410, leaving a cavity 910 in the first partially fabricated memory cell 410. A bit line 1010 comprising a conductive material such as metal is deposited into the cavity 910 in the first partially fabricated memory cell 410, as illustrated in FIG. 10, which shows the deposition and patterning of the bit line 1010.

For additional information on the manufacture, component materials, use and operation of phase change random access memory devices, see U.S. patent application Ser. No. 11/155,067 entitled “Thin Film Fuse Phase Change RAM and Manufacturing Method”, filed on 17 Jun. 2005, owned by the assignee of this application and incorporated by reference as if fully set forth herein.

The invention has been described with reference to specific exemplary embodiments. Various modifications, adaptations, and changes may be made without departing from the spirit and scope of the invention. Accordingly, the specification and drawings are to be regarded as illustrative of the principles of this invention rather than restrictive, the invention is defined by the following appended claims.

We claim:

1. A method for manufacturing a memory device, comprising:
disposing a plurality of layers over a top surface of a memory substrate, the plurality of layers including a programmable resistive memory film;
forming a hard mask having a geometric structure over a top surface of the plurality of layers by high density plasma deposition of a dielectric material with a specified critical dimension, the geometric structure of the hard mask having a base with a left edge and a right edge;
etching vertically through the plurality of layers that exceeds the left edge of the hard mask until reaching the top surface of the memory substrate and etching vertically through the plurality of layers that exceeds the right edge of the hard mask until reaching the top surface of the memory substrate; and
forming a first air gap adjacent to the left side of the programmable resistive memory film and a second air gap adjacent to the right side of the programmable resistive memory film by depositing dielectric over the hard mask and partially into a portion of the plurality of layers, the first and second air gaps dissipating heat emanated from the programmable resistive memory film.

2. The method of claim 1, wherein the forming step comprises forming the hard mask substantially near the center of the top surface of the plurality of layers, thereby at the etching step, producing the programmable resistive memory film that is self-aligned near the center, and thereby at the forming step, producing the first air gap and the second air gap that have about the same critical dimension.

3. The method of claim 1, wherein the geometric structure comprises a triangular-shape structure having a base overlying the plurality of layers.

4. The method of claim 1, wherein the geometric structure comprises a trapezoidal-shape structure having a base overlying the plurality of layers.

5. The method of claim 1, wherein the dielectric material comprises oxide in the high density plasma deposition of oxide.

6. The method of claim 1, wherein the dielectric material comprises silicon nitride in the high density plasma deposition of silicon nitride.

7. The method of claim 1, wherein the depositing dielectric comprises a non-conformal and a low step coverage dielectric deposition.

8. The method of claim 1, after the forming step, further comprising polishing of the dielectric deposited over the hard mask.

9. The method of claim 8, wherein the plurality of layers comprises a top heater layer overlying the programmable resistive memory film.

10. The method of claim 9, wherein the plurality of layers comprises a cap layer overlying the top heater layer.

11. The method of claim 10, after the polishing step, further comprising etching a cap layer from the plurality of layers to create a void.

12. The method of claim 11, after the forming step, further comprising depositing a bit line into the void.

13. The method of claim 1, wherein the plurality of layers comprises the programmable resistive memory film overlying a bottom heater layer.

14. The method of claim 13, wherein the plurality of layers comprises the bottom heater layer overlying a bottom electrode.

15. The method of claim 1, wherein the programmable resistive memory film has a thickness ranging from about 200 Å to about 1000 Å.

16. The method of claim 1 wherein the programmable resistive memory film has at least two solid phases which include a generally amorphous phase and a generally crystalline phase.

17. The method of claim 1, wherein the resistive memory material film comprises GeSbTe.

18. The method of claim 1, wherein the resistive memory material film comprises a combination of two or more materials from the group of Ge, Sb, Te, Se, In, Ti, Ga, Bi, Sn, Cu, Pd, Pb, Ag, S, or Au.

19. The method of claim 1, wherein the resistive memory material film comprises a colossal magnetoresistance material.

20. The method of claim 1, wherein the resistive memory material film comprises a two-element compound.
